(19) United States
(12) Patent Application Publication
(10) Pub. No.: US 2004/0221811 A1
(43) Pub. Date: Nov. 11, 2004

(54) Method and apparatus for processing wafers

(76) Inventors: Robert Mitchell, West Sussex (GB); Keith Relleen, West Sussex (GB); John Ruffell, Sunnyvale, CA (US)

Correspondence Address: Robert Mulcahy, Esq., Legal Affairs Dept., APPLIED MATERIALS, INC., Box 450A, Santa Clara, CA, 95052, US

(21) Appl. No.: 10/732,805

(22) Filed: Dec. 11, 2003

Related U.S. Application Data
(63) Continuation-in-part of application No. 09/996,805, filed on Nov. 30, 2001, now Pat. No. 6,679,675.

(51) Int. Cl. C23C 16/00

(52) U.S. Cl. 118/719

(57) ABSTRACT

An apparatus for processing wafers one at a time. The apparatus has a vacuum chamber 1 into which wafers are loaded through a pair of loadlocks 3, 4 which are spaced one above the other. A robot within the vacuum chamber 1 has a pair of gripper arms 22, 29 which are moveable along and rotatable about a vertical axis 23 so as to be moveable between the loadlocks 3, 4 and a wafer processing position. Each of the loadlocks 3, 4 has an enlarged valve 113, 125 on the vacuum chamber side to allow rotation of the gripper arms 22, 29 in and out of the loadlocks 3, 4.

### FIELD OF THE INVENTION

A present invention relates to a method and apparatus for processing wafers. The invention has particular application to ion implantation chambers for semiconductor wafers.

### BACKGROUND OF THE INVENTION

In such ion implantation chambers, a wafer is scanned across an ion beam to introduce controlled doses of impurities into the wafer. The chamber in which the wafer is processed is evacuated.

In order to load the wafers into the vacuum chamber, a loadlock chamber is used to preserve the vacuum while loading wafers from the outside atmosphere. The loadlock chamber has an external valve to seal the loadlock chamber from the external atmosphere and an internal valve to seal the loadlock chamber from the vacuum chamber. With the internal valve closed and the external valve open, the wafer is loaded into the loadlock chamber from the atmospheric side. The external valve is then closed and the loadlock chamber is evacuated before the internal valve is opened and the wafer is transported into the vacuum chamber for processing. An example of such a loadlock is disclosed in EP-A-604,066.

In order to make most efficient use of the ion beam, and thus increase the throughput of the apparatus, the loading and unloading of the wafers into and out of the vacuum chamber must be done as quickly as possible. The present invention aims to improve the performance of the apparatus in this respect.

### SUMMARY OF THE INVENTION

From a first aspect, the present invention resides in a loadlock assembly for use with a wafer-processing apparatus including a vacuum chamber, the loadlock assembly comprising a loadlock arranged for transporting wafers from external atmosphere to the vacuum chamber, the loadlock having a first valve which is selectively operable to seal the loadlock from the external atmosphere, a second valve which is selectively operable to seal the loadlock from the interior of the vacuum chamber, and a port for evacuating and pressurizing the loadlock, wherein the first valve has a first width to accommodate wafers transported linearly through the first valve and the second valve has a second width larger than the first width to accommodate wafers transported through the second valve on an arcuate path centred on an axis perpendicular to the second width located on the vacuum chamber side of the second valve.

Such an arrangement is advantageous as it allows wafers to be transported from the loadlock to the interior of the vacuum chamber using rotation along an arcuate path, rather than the commonly-used linear translation. This reduces the complexity of the mechanism that transports wafers from loadlock into the interior of the vacuum chamber.

Optionally, the ratio of the second width to the first width is at least 1.2 to 1.

Preferably, the first and second valves are slit valves in which a gate member is raised and lowered to uncover a slit allowing access to the loadlock. Conveniently, the first and second widths extend in parallel. Optionally, the first valve is laterally offset relative to the second valve towards the axis.

Preferably, the loadlock assembly has a shape that narrows from the second valve to the first valve.

Optionally, the loadlock assembly further comprises a closure located between the first and second valves that is operable to open to allow access to the loadlock: conveniently, the closure may be a hinged lid.

From a second aspect, the present invention resides in a loadlock assembly for use with wafer-processing apparatus including a vacuum chamber, the loadlock assembly comprising first and second loadlocks arranged to be relatively stacked and arranged for transporting wafers from external atmosphere to the vacuum chamber, the first and second loadlocks having respective first and second outer valves which are selectively operable to seal the loadlocks from the external atmosphere, respective first and second inner valves which are selectively operable to seal the loadlocks from the interior of the vacuum chamber, and respective ports for evacuation and pressurization of the loadlocks, wherein the first and second outer valves have a first width to accommodate wafers transported through the first and second outer valves, and the first and second inner valves have a second width larger than the first width to accommodate wafers transported through the first and second inner valves on an arcuate path centred on an axis perpendicular to the second width and located on the vacuum chamber side of the first and second inner valves.

The use of two loadlocks which are preferably single wafer loadlocks allows wafers to be transported in parallel through the two loadlocks.

Optionally, the first and second inner valves and the first and second outer valves both comprise opposed slit valves. Preferably, the width of the first and second inner valves and the width of the first and second outer valves all extend in parallel with one another. Conveniently, the loadlock assembly further comprises first and second hinged lids located between the first and second inner valves and the first and second outer valves.

From a third aspect, the present invention resides in a loadlock assembly for use with a wafer-processing vacuum chamber, the loadlock assembly comprising a loadlock arranged to transport wafers from external vacuum to the vacuum chamber, a first side of the loadlock having a first valve selectively operable to seal the loadlock from the external atmosphere, the first valve having a first width, a second side end of the loadlock having a second valve selectively operable to seal the loadlock from the interior of the vacuum chamber, the second valve having a second width, the loadlock further comprising a port for evacuating and pressurizing the loadlock, wherein the first width is smaller than the second width and wherein the width of the interior of the loadlock assembly narrows progressively from the second side to the first side.

Such a tapering shape has the benefit of reducing the volume of the loadlock that must be evacuated.

Preferably, the first and second widths extend in parallel with one another and the first valve is offset relative to the second valve in substantially the same direction as the first and second widths.

From a fourth aspect, the present invention resides in a loadlock assembly for attachment in a predetermined orientation to an apparatus operative to process wafers comprising a vacuum chamber in which the wafers are processed at a wafer processing position and a mechanism for transporting the wafers from the loadlock assembly to a wafer processing position, the mechanism comprising a gripper arm for holding the wafers and a robot operable to provide rotational motion of said gripper arm at a fixed distance about a predetermined axis; the loadlock assembly comprising: a loadlock through which wafers are loaded into the vacuum chamber, the loadlock having an outer valve which is selectively operable to seal the loadlock from the external atmosphere, an inner valve which is selectively operable to seal the loadlock from the interior of the vacuum chamber, and a port for evacuation and pressurization of the loadlock, the loadlock being arranged, when attached to the apparatus, to transport wafers in a plane perpendicular to the axis at the same radial distance from the axis so as to be engageable by the gripper arm, and wherein the inner valve is sized to allow access, when attached to the apparatus, by the gripper arm to wafers in the loadlock by rotation of the robot about the axis without a substantial change in the distance of the gripper arm from the axis.

From a fifth aspect, the present invention resides in a loadlock assembly for attachment in a predetermined orientation to an apparatus operative to process wafers comprising a vacuum chamber in which the wafers are processed at a wafer processing position, and a mechanism for transporting the wafers from the loadlock assembly to the wafer processing position comprising a gripper arm for holding wafers and a robot operable to provide rotational motion of said gripper arm at a fixed radial distance about a predetermined axis; the loadlock assembly comprising: first and second loadlocks through which wafers are loaded into the vacuum chamber, the first and second loadlocks having respective first and second outer valves which are selectively operable to seal the loadlocks from the external atmosphere, respective first and second inner valves which are selectively operable to seal the loadlocks from the interior of the vacuum chamber, and respective parts for evacuation and pressurization of the loadlocks, the loadlocks being relatively stacked and arranged when attached to the apparatus to transport wafers in respective planes perpendicular to the axis at the same radial distance from the axis so as to be engageable by the gripper arm, and wherein the first and second inner valves are sized to allow access, when attached to the apparatus, by the gripper arm to wafers in the loadlocks by rotation of the robot about the axis without a substantial change in the distance of the gripper arm from the axis.

From a sixth aspect, the present invention resides in an apparatus for processing wafers comprising a vacuum chamber in which the wafers are serially processed at a wafer processing position, a loadlock through which the wafers are loaded into the vacuum chamber, and a mechanism for transporting the wafers from the loadlock to the wafer processing position, the loadlock having an outer valve which is selectively operable to seal the loadlock from the external atmosphere, an inner valve which is selectively operable to seal the loadlock from the interior of the vacuum chamber, and a part for evacuation and pressurization of the loadlock, the mechanism for transporting comprising a gripper arm for holding wafers, and a robot operable to provide rotational motion of the gripper arm at a fixed radial distance about a predetermined axis, the loadlock being arranged to transport wafers in a plane perpendicular to the axis at the same radial distance from the axis so as to be engageable by the gripper arm, and wherein the inner valve is sized to allow access by the gripper arm to wafers in the loadlock by rotation of the robot about the axis without a substantial change in the distance of the gripper arm from the axis.

From a seventh aspect, the present invention resides in an apparatus for processing wafers comprising a vacuum chamber which the wafers are serially processed at a wafer processing position, first and second loadlocks through which the wafers are loaded into the vacuum chamber, and a mechanism for transporting the wafers from the loadlocks to the wafer processing position, the first and second loadlocks having respective first and second outer valves which are selectively operable to seal the loadlocks from the external atmosphere, respective first and second inner valves which are selectively operable to seal the loadlocks from the interior of the vacuum chamber, and respective ports for evacuation and pressurization of the loadlocks, the mechanism for transporting comprising a gripper arm for holding wafers, and a robot operable to provide rotational motion of the gripper arm at a fixed radial distance about a predetermined axis, the loadlocks being relatively stacked and arranged to transport wafers in respective parallel planes perpendicular to the axis at the same radial distance from the axis so as to be engageable by the gripper arm, and wherein the first and second inner valves are sized to allow access by the gripper arm to wafers in the loadlocks by rotation of the robot about the axis without a substantial change in the distance of the gripper arm from the axis.

The use of two loadlocks which are preferably single wafer loadlocks allows wafers to be transported in parallel through the two loadlocks. Preferably a gripper arm is provided which is rotatable about an axis to access the loadlocks, and both loadlocks are positioned at the same radial distance from this axis. This allows the mechanisms for loading and unloading both loadlocks on one side of the loadlocks to share certain common parts. Preferably, the loadlocks are positioned one substantially directly above the other to allow this to be achieved with little or no increase in the footprint of the apparatus.

The wafers from both loadlock chambers can be picked up and set down by a robot which requires only axial motion in the direction of the axis about which the gripper arm is pivoted, and rotational motion about this axis. In fact, in order to allow a processed wafer to be loaded into the loadlock while an unprocessed wafer is being unloaded, a second gripper arm will be provided which is axially movable together with the first gripper arm. The second gripper arm is either disposed on the opposite side of the axis to the first gripper arm and is rotatable with the first gripper arm, or is positioned immediately below the first gripper arm and is rotatable about the axis independently of the first gripper arm. In the second case, which is preferred as it offers greater flexibility, the robot in the vacuum chamber is a three axis robot, having one linear and two rotational axes. This is advantageous over a conventional four axis robot as each additional axis required in a vacuum chamber increases the cost and the maintenance of the apparatus.

### BRIEF DESCRIPTION OF THE DRAWINGS

An example of a method and apparatus in accordance with the present invention will now be described with reference to the accompanying drawings, in which:

FIG. 1 is a schematic cross-section from one side through two loadlock chambers and a portion of the vacuum chamber, that shows a first embodiment of the present invention;

FIG. 2 is a schematic plan view of the arrangement shown in FIG. 1;

FIG. 3 is a perspective view of the upper loadlock with the lid valve removed;

FIG. 4 is a cross-section of the drive mechanism for the two gripper arms in the vacuum chamber;

FIG. 5 is a throughput graph showing the movements of the various components of the apparatus;

FIG. 6 is a schematic cross section from one side through two loadlock chambers and a portion of the vacuum chamber, that shows a second embodiment of the present invention;

FIG. 7 is a schematic plan view of the arrangement shown in FIG. 6;

FIG. 8 is a perspective view of the twin loadlock system of FIG. 6; and

FIG. 9 corresponds to FIG. 8 but shows the lids in an open position; and

FIG. 10 is a geometrical sketch illustrating the widths of the valves of the twin loadlock system of FIG. 6.

### DETAILED DESCRIPTION OF THE PREFERRED EMBODIMENTS

The ion implantation apparatus is broadly the same as that disclosed in WO99/13488.

The apparatus comprises a vacuum chamber into which wafers are loaded independently onto an electrostatic chuck (hereafter referred to as an e-chuck). In operation an individual wafer is electrostatically clamped on the e-chuck and is held to be scanned by a horizontally scanning ion beam.

The arm which supports the e-chuck extends out of the vacuum chamber and is supported by a linear motion mechanism for reciprocably moving the e-chuck vertically so that the entire surface of a wafer on the e-chuck is scanned by the ion beam. The linear motion mechanism itself is mounted so as to be rotatable about a horizontal tilt axis which allows the angle between the wafer and the ion beam to be varied. The e-chuck is further provided with a mechanism for rotating the wafer about an axis passing through a centre of the wafer and perpendicular to the plane of the wafer. The mechanism thus far described is as that shown in WO99/13488. Further, the arm itself is independently rotatable about the horizontal tilt axis through 90° so that it can be moved from the vertical scanning position to a horizontal loading position.

The arrangement described above corresponds to where scanning of the ion beam across the wafer is accomplished using horizontal scanning of the ion beam and vertical scanning of the wafer on the e-chuck. This is but one possible arrangement: alternatives include scanning the ion beam both horizontally and vertically relative to a stationary wafer, and scanning the wafer both horizontally and vertically relative to a fixed ion beam.

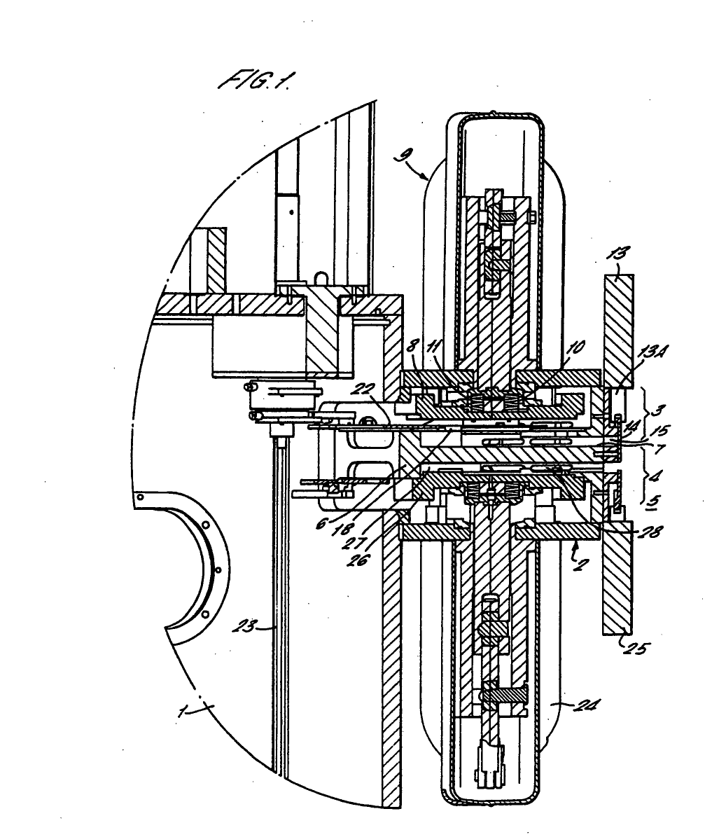

An example of an ion implantation apparatus to which the present invention can be applied according to a first embodiment will now be described with reference to FIGS. 1 to 5.

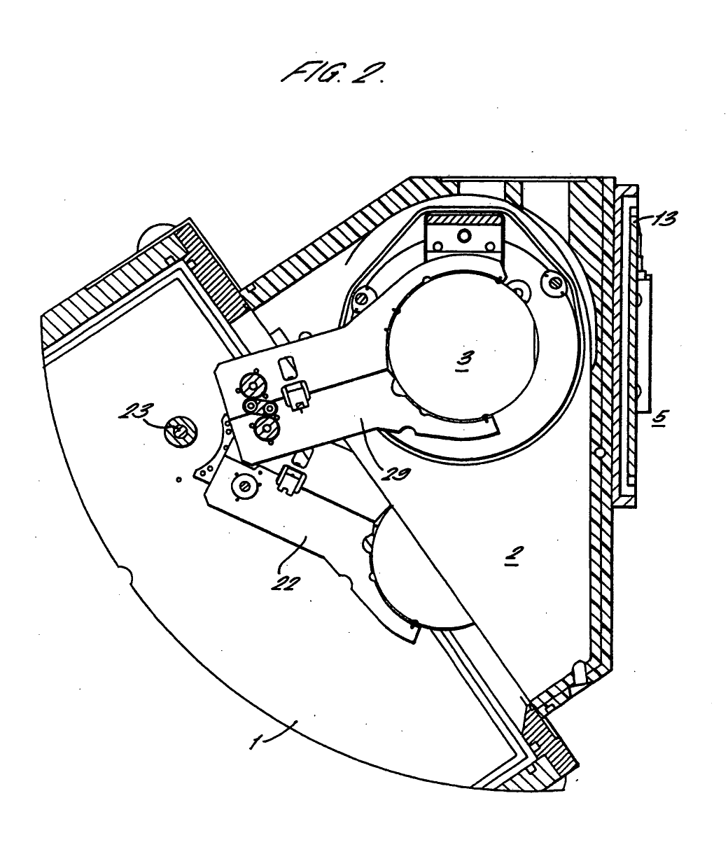

The arrangement for loading the wafers into the vacuum chamber is shown in FIGS. 1 and 2. The apparatus broadly comprises the vacuum chamber 1 containing the e-chuck (not shown), a loadlock assembly 2 comprising an upper loadlock 3 and a lower loadlock 4, and an external atmospheric portion 5. The upper loadlock 3 is directly above the lower loadlock 4 in the sense that the wafers retained in the two loadlocks have their centres on the same vertical axis.

In the external atmospheric portion 5 are a number of magazines which provide a source of wafers to be treated in the ion implantation apparatus, and receive the treated wafers from the ion implantation apparatus.

The loadlock assembly 2 comprises a loadlock housing 6 which has a central plate 7 separating the upper 3 and lower 4 loadlocks. The upper 3 and lower 4 loadlocks are positioned as close together as possible in the vertical direction to minimise the movement required to load and unload wafers from both loadlocks. The upper loadlock 3 is provided with a lid valve 8 which is elevationally movable by a cam mechanism 9 mounted directly above the upper loadlock 3. A bellows 10 provides a vacuum seal for the cam actuator 9, and a spring 11 provides a degree of preloading for the lid valve 8, and absorbs any dimensional tolerances between the lid valve 8 and the housing 6. To provide access for a wafer 12 into the vacuum chamber 1, the lid valve 8 is raised to the position shown in FIG. 1 allowing lateral access to the wafer 12 on the depending feet for a gripper arm as described below. In FIG. 1 the upper loadlock 3 is shown open to the vacuum chamber 1 with the wafer being in the process of being removed into the vacuum chamber 1. Access to the atmospheric side of the upper loadlock 3 is provided by a slit valve 13 in which the gate element 14 can be raised and lowered on an activator 13A in order to seal across a slit 15 through which the wafer 12 can enter the upper loadlock 3.

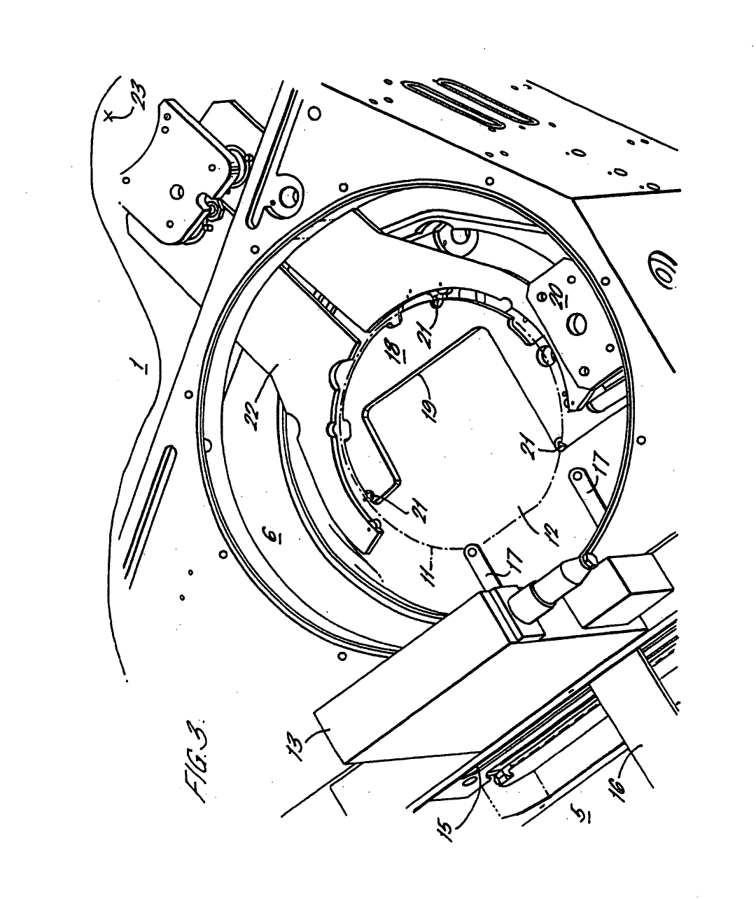

The mechanism for loading and unloading a wafer 12 from the upper loadlock 3 is shown in more detail in FIG. 3. It should be understood that this figure is schematic, in the sense that it shows both the valve to the vacuum chamber 1 and the valve to atmosphere 5 open and the mechanisms for transferring the wafer 12 from either side being deployed into the loadlock. Of course, in practice, only one valve will be open at any one time, and only one of the deployment mechanisms will be in place.

An end effector 16 of an atmospheric robot is shown projecting through the slit 15. Within the upper loadlock 3, the end effector 16 is represented by a pair of parallel fingers 17, but in practice will project beneath the wafer 12 shown in outline only in FIG. 3, so as to support the wafer 12. A loadlock carrier 18 is provided to support the wafer 12 in the loadlock 3. The loadlock carrier 18 has an outer profile which substantially matches the circular profile of the wafer 12. The opposite side of the loadlock carrier 18 has straight sided recess 19 which is shaped so as to allow the end effector 16, 17 to pass through the loadlock carrier 18 from above as will be described. The loadlock carrier 18 has an upwardly projecting flange which leads up to a bracket 20 with which it is integral. This bracket 20 is rigidly fixed to the lid valve 8, so that the whole loadlock carrier 18 moves up and down with the lid valve 8. Three feet 21 are provided on the upper surface of the loadlock carrier 18 so as to receive the wafer 12. When the lid valve 8 is raised, the loadlock 3 can be accessed by a gripper arm 22 moving in a horizontal plane about a vertical axis 23.

In order to place a wafer 12 on the loadlock carrier 18, the end effector 17 carrying a wafer 12 is moved through the slit 15 as shown in FIG. 3. The end effector 17 is then moved downwardly through the recess 19 in the loadlock carrier 18 until the wafer 12 is supported by the three feet 21. The end effector 17 is then moved further downwardly so as to be clear of the wafer 12 and is then withdrawn through the slit 15. All of this is done with the lid valve 8 in its lowered or closed position. Once the loadlock chamber has been evacuated, the lid valve 8 is raised, bringing the loadlock carrier 18 and wafer 12 with it. The gripper arm 22 is then swung into the position shown in FIG. 3, and is then moved downwardly, or the loadlock carrier 18 is moved upwardly so that it can grip the edge of the wafer 12 and withdraw it from the loadlock carrier 18.

The lower loadlock 4 has a similar design to the upper loadlock 3, in that the cam mechanism 24 and slit valve 25 are of the same construction, but in an inverted configuration. In the lower loadlock 4, there is no need to provide a loadlock carrier 18 to support the wafer 12, as the wafer 12 can be directly supported by feet on the upper surface of lower lid valve 26. The lower lid valve 26 will need a recess of similar shape to the recess 19 between the feet to allow the end effector 17 to place the wafer 12 on the feet and be withdrawn.

In FIG. 1 the lower loadlock 4 is shown in its raised/closed position in which the lower lid valve 26 seals around its periphery with the housing 6 thereby providing a seal between the lower loadlock 4 and the vacuum chamber 1 and defining a sealed loadlock chamber 27 between the lower surface of plate 7 of the housing 6 and the upper surface of lower lid valve 26. The volume of the loadlock chambers of the upper 3 and lower 4 loadlocks is kept to a minimum to minimise the pumping and venting required.

In the configuration of FIG. 1 and with slit valve 25 open, a wafer 12 can be loaded into the loadlock chamber 27 and is supported by the feet on the lower lid valve 26. The slit valve 25 is then closed and the loadlock chamber 27 is evacuated through evacuation port 28. The lower lid valve 26 can then be lowered breaking the seal on the vacuum chamber side and providing access to the loadlock chamber 27 from the vacuum chamber 1.

The robot mechanism for transferring the wafers from the loadlock mechanism 2 to the e-chuck will now be described in more detail. In addition to the gripper arm 22 shown in FIG. 3, which will subsequently be referred to as the lower gripper arm 22, the robot further comprises upper gripper arm 29 of the same construction. The two arms are mounted adjacent to one another so as to be movable together along a vertical axis 23 and rotatable independently about the vertical axis 23.

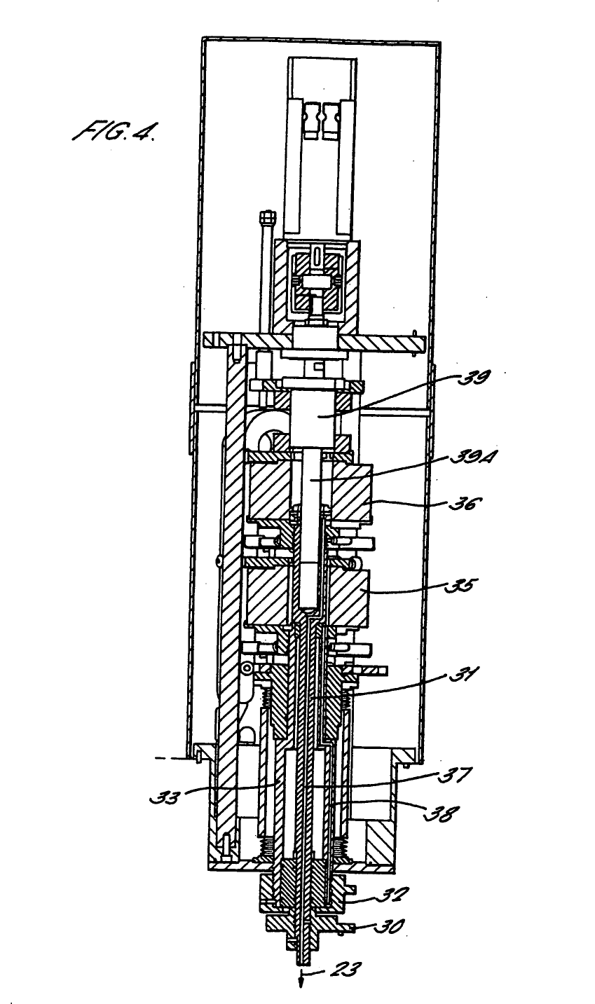

The mechanism for operating the gripper arms 22, 29 is shown in FIG. 4. The lower gripper arm 22 is attached via hub 30 to an inner shaft 31. The upper gripper arm 29 is attached via hub 32 to an outer shaft 33. The inner shaft 31 is rotated by a motor 35, while the outer shaft 33 is rotated by motor 36. Vacuum seals for the two shafts 31, 33 are provided by ferro-fluidic seals. Air ducts 37, 38 allow the transmission of air to the gripper arms 22, 29 for the pneumatic opening and closing operations of these arms 22, 29. A third motor 39 rotates a feed screw shaft 39A to provide the axial movement of the two gripper arms 22, 29 together along the axis 23.

The purpose having the pair of gripper arms 22, 29 is that when one is unloading a wafer 12 at a particular location, the other can immediately load a wafer 12 at that location without having to wait for the first one to return with a further wafer 12 for loading. The e-chuck may be at the same elevational height as one of the loadlocks 3, 4, such that elevational movement of the gripper arms 22, 29 is only required when moving wafers 12 between the e-chuck and the loadlock which is elevationally offset from the e-chuck. On the other hand, the e-chuck may be elevationally between the two loadlocks, requiring a smaller elevational movement of the gripper arms 22, 29 each time a wafer is transferred.

The entire loading/unloading operation of this apparatus will now be described with particular reference to FIG. 5. The key to this figure is that five components, namely e-chuck (c), top arm, lower arm, top loadlock (LU), lower loadlock (LL) and the robot for loading wafers from the atmospheric side into the two loadlocks are listed in the left hand column. The operation of each of these components at any one time is listed in the shaded boxes immediately to the right of each listed component. The letters included in these boxes refer to the location to which the component has travelled at any particular time. For example, the box containing (c) in the line indicating the position of the lower arm means that, at this time, the lower arm is at the e-chuck. The letter (M) in the line for the robot refers to a magazine on the atmospheric side supplying wafers to the implant apparatus, and the letters (or) in the line for the robot refer to an ion orientation apparatus for correctly orientating the wafer before it is placed in the loadlock mechanism 2.

The operation of the apparatus can most clearly be described by referring to the passage of a single wafer (hereafter referred to as the wafer in question) through the apparatus from the time that an untreated wafer leaves the magazine (M) to the time that the treated wafer is returned to the magazine (M). It should be understood that, every time the wafer is deposited at a particular location, the wafer which is one step ahead of the wafer in question will just have been removed from this location. Also each time the wafer is picked up from a particular location, it will be replaced by a later wafer which is one stage behind in the process.

The wafer in question is picked up by the atmospheric robot from the magazine (M) and transferred to the orientation mechanism (or) where it is rotated to the correct orientation as shown at 40 in FIG. 5. On its next pass, the atmospheric robot picks the wafer in question out of the orientation mechanism (or) and transfers it to the lower loadlock 4. At this time, the apparatus has the lower slit valve 25 open and the lower lid valve 26 raised. Once the wafer in question is in place, the slit valve 25 is closed and the loadlock chamber 27 is evacuated as shown at 41 in FIG. 5. It will be understood that the atmospheric robot loads the upper 3 and lower 4 loadlocks alternately as shown on the bottom line of FIG. 5.

Once the loadlock chamber 27 is evacuated, the lower lid valve 26 is lowered by the cam mechanism 24. The wafer in question is now in a position in which it can be gripped by upper gripper arm 29 as indicated at 42 in FIG. 5. As mentioned above, it will be understood that the lower arm 22 then moves a treated wafer in the opposite direction into the lower loadlock 4 as indicated at 43 in FIG. 5. The upper gripper arm 29 with the wafer in question then rotates about axis 23 towards the e-chuck and waits. While this is happening, the lower gripper arm 22 which is now not carrying a wafer moves to the e-chuck and picks up the wafer which has just been scanned as indicated at 44 and FIG. 5. The wafer in question is then put onto the e-chuck as indicated at 45 in FIG. 5. The e-chuck is then electrostatically activated to attract the wafer in question to the chuck, and is rotated from its horizontal loading configuration to a vertical scanning configuration which takes approximately one second and is illustrated at 46 in FIG. 5. The wafer in question is then scanned with the ion beam as previously described and as indicated in 47 in FIG. 5. Once this operation is complete, the e-chuck returns to the horizontal loading configuration as indicated by 48 in FIG. 5, whereupon the lower gripper arm 22 retrieves the wafer in question as illustrated at 49 in FIG. 5. The upper gripper arm 29 loads the next wafer to be treated onto the e-chuck as indicated at 50 in FIG. 5. The lower arm then rotates about axis 23 and transports the wafer in question to the lower loadlock 4 as indicated at 51 in FIG. 5. At this time, the lower lid valve 26 is in its lowered position and the slit valve 25 is closed. Once the wafer in question is in place, the lower lid valve 26 is raised and the loadlock chamber 27 is vented back to atmospheric pressure as indicated at 52 in FIG. 5 through port 28, or a separate port. Once the chamber has been vented, the slit valve 25 opens and the wafer is collected by the atmospheric robot and returned to the magazine containing completed wafers.

As is apparent from FIG. 5, while one of the loadlocks 3, 4 is being pumped to vacuum, the other is being vented to atmosphere almost simultaneously, but slightly later. This means that while the treated wafer is being transported out of the vacuum chamber 1 through one loadlock, an untreated wafer is being transported in through the other. This allows a regular supply of wafers to the e-chuck, thereby reducing the gap between implant operations.

With this apparatus it will be possible to process up to 270 wafers per hour, as opposed to about 200 per hour in the prior art.

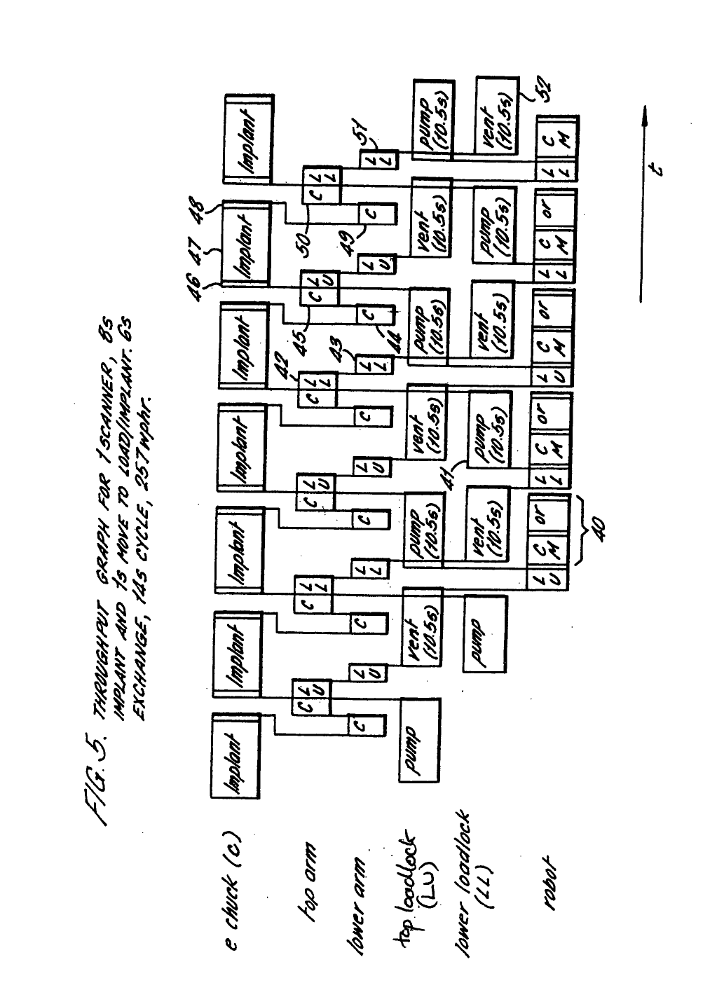

FIGS. 6 to 9 show another example of an ion implantation apparatus to which the present invention can be applied according to a second embodiment of the present invention. This second embodiment corresponds broadly to the first embodiment of FIGS. 1 to 4 and, therefore, like reference numerals will be used for like parts and similar parts will not be described to avoid undue repetition.

The robot mechanism for transferring the wafers from the loadlock mechanism to the e-chuck is exactly as described for the first embodiment. This correspondence includes its position within the vacuum chamber 1 relative to the position of the loadlock mechanism 2 such that rotation of the gripper arms 22, 29 starts and ends from the same positions within the vacuum chamber 1 and the upper 3 and lower 4 loadlocks. In addition, the mechanism for operating the gripper arms 22, 29 is also exactly as described for the first embodiment and as shown in FIG. 4.

As per the first embodiment, the loadlock assembly 2 comprises a loadlock housing 6 which has a central plate 7 separating the upper 3 and lower 4 loadlocks. As can be seen from FIG. 6, the main difference in the second embodiment lies in that the interface between the loadlock assembly 2 and the vacuum chamber 1 is defined by a second pair of vacuum-side slit valves 113, 125 that replace the lid valves 8 and 26. The first air-side 13, 25 and second vacuum-side 113, 125 pairs of slit valves are arranged to be parallel and at corresponding heights, although the width of the vacuum-side pair of slit valves 113, 125 exceeds that of the air-side pair 13, 25.

In common with the first embodiment, the loadlock mechanism 2 of the second embodiment is operable to cooperate with the same end effector 16 of the same atmospheric robot. Within each loadlock 3, 4, three upwardly-projecting feet 121 are provided to support the wafer 12 and to define a recess as previously described for the lower loadlock 4. Each of the feet 121 is L-shaped such that the wafer 12 is supported around and beneath its edge on the shoulder of each foot 12. In order to place a wafer 12 into the upper loadlock 3 from atmosphere, the end effector 17 carrying a wafer 12 is moved through slit 15, shown in a closed position in FIG. 6. The end effector 17 is then moved downwardly through the recess between the feet 121 until the wafer 12 is supported on the feet 121. The end effector 17 continues to move downwardly so as to be clear of the wafer 12 and is then withdrawn back through the slit 15.

All of the above is performed with the vacuum-side slit valve 113 in its lowered or closed position. With the wafer 12 in place on the feet 121, the air-side slit valve 13 can be closed and the upper loadlock 3 evacuated ready for transfer of the wafer 12 into the vacuum chamber 1. To provide access for a wafer 12 into the vacuum chamber 1, the vacuum-side slit valve 113 is raised to the position shown in FIG. 6 allowing lateral access to a wafer 12 positioned within the upper loadlock 3. In FIG. 6, the upper loadlock 3 is shown open to the vacuum chamber 1 with the wafer 12 being in the process of being removed into the vacuum chamber 1. Vacuum-side slit value 113 has the same design as air-side slit valve 13 (although wider) such that access to the atmospheric side of the upper loadlock 3 is provided by a gate element 114 of vacuum-side slit value 113 that can be raised and lowered on an activator 113A in order to seal across a slit 115 through which a wafer 12 can enter the upper loadlock 3. This vacuum-side slit valve 113 is shown in a closed position in FIG. 6.

With the vacuum-side slit valve 113 open, the lower gripper arm 22 can then be swung into position into the upper loadlock 3 and moved downwardly so that the gripper arm 22 can grip the edge of the wafer 12 and withdraw it from the loadlock 3. It will be noted that the wafer 12 is maintained at a constant height held by the feet 121 whilst the vacuum-side slit valve 113 is opened, in contrast with the first embodiment where the wafer 12 moves to a different height as the lid valve 8 opens.

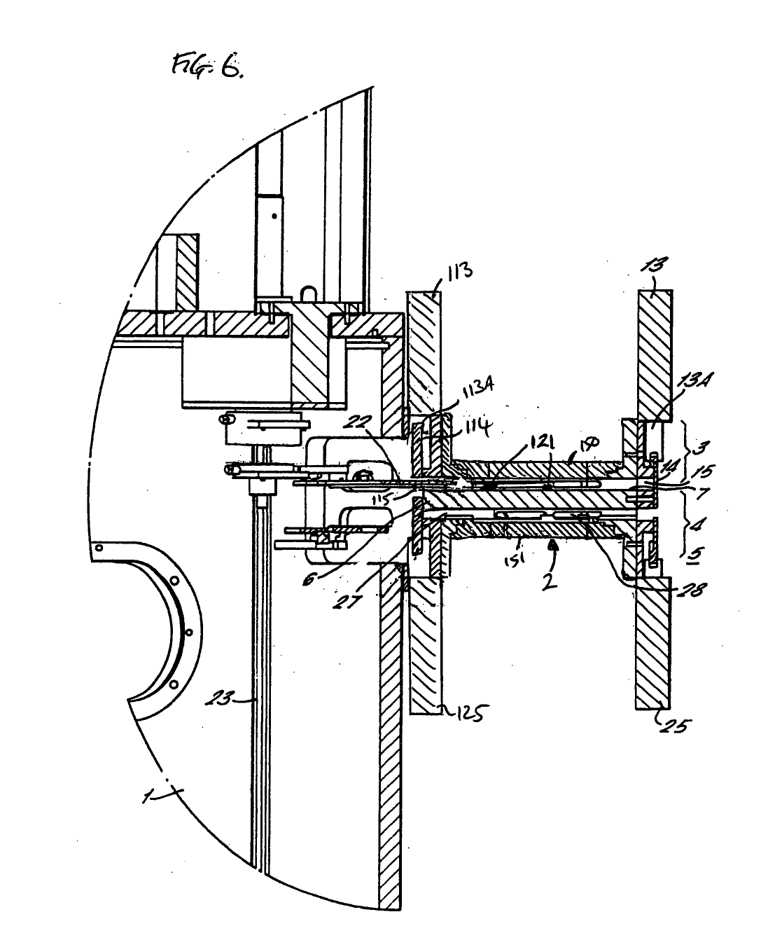

Obviously, transfer of wafer 12 to the e-chuck can be performed equally well using the upper gripper arm 29. As can be seen best from FIG. 7, the vacuum-side slit valve 113 has a wider bore than air-side slit valve 13 to allow sufficient clearance for gripper arms 22, 29 to rotate into the upper loadlock 3 (the end effector 16 moves linearly into loadlock 3 thereby requiring less clearance through air-side slit 15).

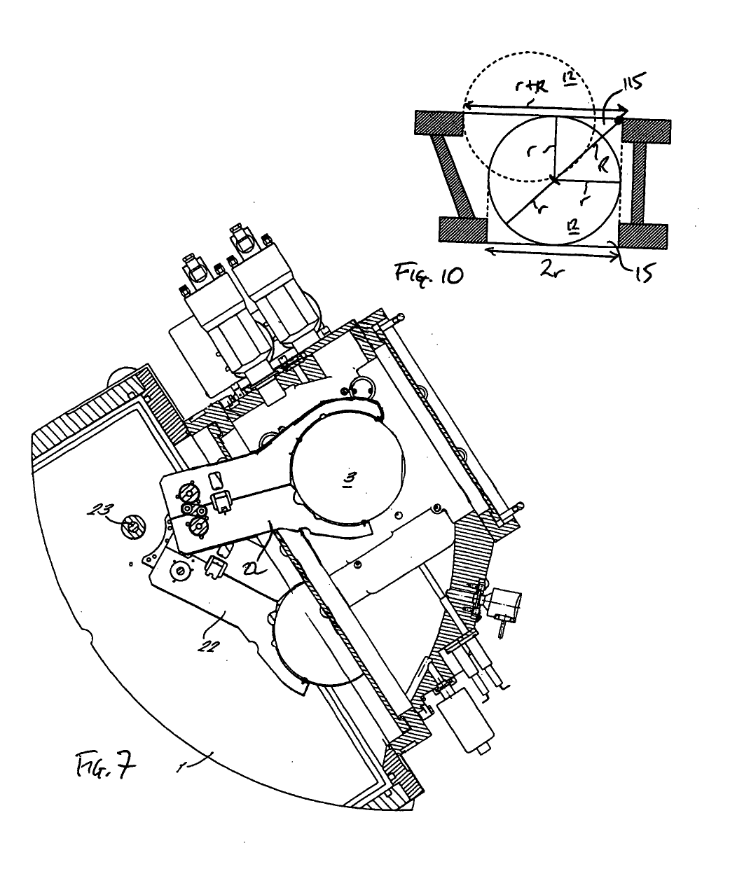

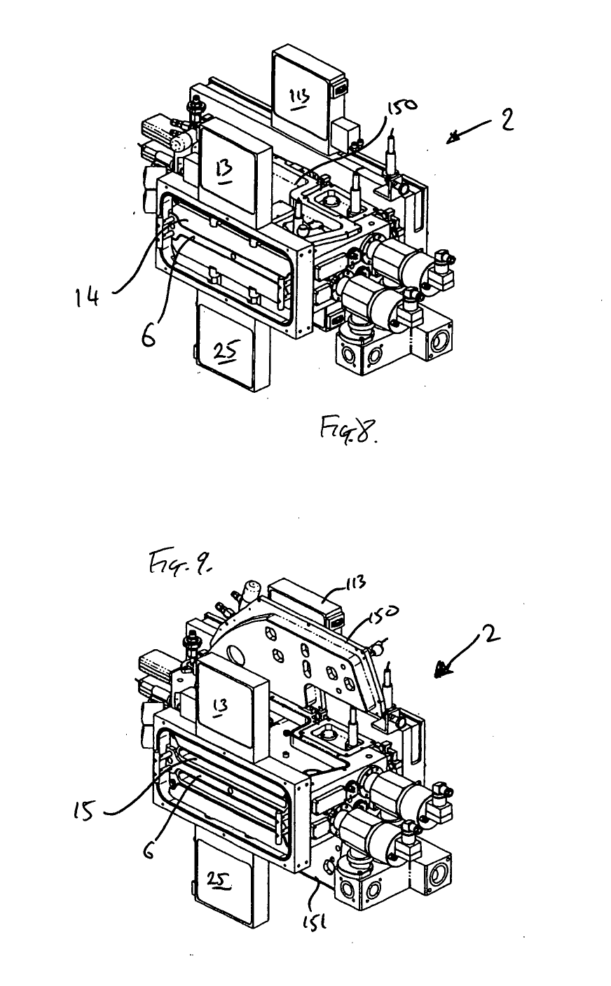

The minimum size of the vacuum-side slit 115 relative to the air-side slit 15 can be determined by the simple geometric consideration shown in FIG. 10. Placing the axis 23 of the gripper arm 22 at an ideal location in the corner of vacuum-side slit 115 produces a width of r+R for the vacuum-side slit 115, where r is the wafer radius and R is the radius from the axis 23 to the centre of the wafer 22. The minimum width of the air-side slit 15 is simply 2r. Inspection of FIG. 10 shows that R is related to r by Pythagoras' equation giving R²=r²+r², i.e. R=r√2. This gives a minimum vacuum-side slit width of r+r√2, i.e. r(1+√2). Hence, the ratio of vacuum-side slit width to air-side slit width is r(1+√2):2r which approximately equals 1.2:1.

The lower loadlock 4 has a corresponding design to the upper loadlock 3, except that the slit valves 25 and 125 are inverted. As for the upper loadlock 3, the lower loadlock 4 is provided with three feet 121 to support a wafer 12. In FIG. 6, the lower loadlock 4 is shown with the vacuum-side slit valve 125 in a closed position thereby sealing the lower loadlock 4 from the vacuum chamber 1 and with the air-side slit valve 25 open such that the lower loadlock 4 is at atmospheric pressure and is accessible by the robot mechanism that transfers wafers 12 into the loadlock mechanism 2 from atmosphere. As before, the volume of loadlocks 3, 4 is kept to a minimum to minimise the pumping and venting required. This is particularly beneficial because pumping and venting is performed in a controlled, progressive manner. Transfer of wafers 12 through lower loadlock 4 is as per previously described for upper loadlock 3.

A disadvantage of the first embodiment is that it is difficult to access loadlocks 3, 4 for cleaning and maintenance purposes because of the cam mechanisms provided to open and close the lid valves 8 and 26. The design of the second embodiment is an improvement in that provision of slit valves 13, 113, 25 and 125 at either end of the loadlock mechanism 2 allows lids 150, 151 to be provided centrally on upper and lower surfaces respectively of the loadlock assembly 2. The lids 150, 151 are hinged to swing open and provide easy access into loadlocks (3 and 4) for cleaning and maintenance as best seen in FIGS. 8 and 9. FIG. 8 shows the lids 150, 151 and air-side slit valves 13, 25 in a closed position and FIG. 9 shows the lids 150, 151 and air-side slit valves 13, 25 in an open position.

What is claimed is:

1. A loadlock assembly for use with a wafer-processing apparatus including a vacuum chamber, the loadlock assembly comprising a loadlock arranged for transporting wafers from external atmosphere to the vacuum chamber, the loadlock having a first valve which is selectively operable to seal the loadlock from the external atmosphere, a second valve which is selectively operable to seal the loadlock from the interior of the vacuum chamber, and a port for evacuating and pressurizing the loadlock, wherein the first valve has a first width to accommodate wafers transported linearly through the first valve and the second valve has a second width larger than the first width to accommodate wafers transported through the second valve on an arcuate path centred on an axis perpendicular to the second width located on the vacuum chamber side of the second valve.

2. A loadlock assembly according to claim 1, wherein the ratio of the second width to the first width is at least 1.2 to 1.

3. A loadlock assembly according to claim 1, wherein the first and second valves are slit valves.

4. A loadlock assembly according to claim 3, wherein the first and second widths extend in parallel.

5. A loadlock assembly according to claim 4, wherein the first valve is laterally offset relative to the second valve towards the axis.

6. A loadlock assembly according to claim 1, wherein the loadlock assembly has a shape that narrows from the second valve to the first valve.

7. A loadlock assembly according to claim 1, further comprising a closure located between the first and second valves that is operable to open to allow access to the loadlock.

8. A loadlock assembly according to claim 7, wherein the closure is a hinged lid.

9. A loadlock assembly for use with wafer-processing apparatus including a vacuum chamber, the loadlock assembly comprising first and second loadlocks arranged to be relatively stacked and arranged for transporting wafers from external atmosphere to the vacuum chamber, the first and second loadlocks having respective first and second outer valves which are selectively operable to seal the loadlocks from the external atmosphere, respective first and second inner valves which are selectively operable to seal the loadlocks from the interior of the vacuum chamber, and respective ports for evacuation and pressurization of the loadlocks, wherein the first and second outer valves have a first width to accommodate wafers transported through the first and second outer valves, and the first and second inner valves have a second width larger than the first width to accommodate wafers transported through the first and second inner valves on an arcuate path centred on an axis perpendicular to the second width and located on the vacuum chamber side of the first and second inner valves.

10. A loadlock assembly according to claim 9, wherein the first and second inner valves and the first and second outer valves both comprise opposed slit valves.

11. A loadlock assembly according to claim 9, wherein the width of the first and second inner valves and the width of the first and second outer valves all extend in parallel with one another.

12. A loadlock assembly according to claim 9 further comprising first and second hinged lids located between the first and second inner valves and the first and second outer valves.

13. A loadlock assembly for use with a wafer-processing vacuum chamber, the loadlock assembly comprising a loadlock arranged to transport wafers from external vacuum to the vacuum chamber, a first side of the loadlock having a first valve selectively operable to seal the loadlock from the external atmosphere, the first valve having a first width, a second side end of the loadlock having a second valve selectively operable to seal the loadlock from the interior of the vacuum chamber, the second valve having a second width, the loadlock further comprising a port for evacuating and pressurizing the loadlock, wherein the first width is smaller than the second width and wherein the width of the interior of the loadlock narrows progressively from the second side to the first side.

14. A loadlock assembly according to claim 13, wherein the first and second widths extend in parallel with one another and the first valve is offset relative to the second valve in substantially the same direction as the first and second widths.

15. A loadlock assembly for attachment in a predetermined orientation to an apparatus operative to process wafers comprising a vacuum chamber in which the wafers are processed at a wafer processing position and a mechanism for transporting the wafers from the loadlock assembly to a wafer processing position, the mechanism comprising a gripper arm for holding the wafers and a robot operable to provide rotational motion of said gripper arm at a fixed distance about a predetermined axis; the loadlock assembly comprising:
a loadlock through which wafers are loaded into the vacuum chamber, the loadlock having an outer valve which is selectively operable to seal the loadlock from the external atmosphere, an inner valve which is selectively operable to seal the loadlock from the interior of the vacuum chamber, and a port for evacuation and pressurization of the loadlock, the loadlock being arranged, when attached to the apparatus, to transport wafers in a plane perpendicular to the axis at the same radial distance from the axis so as to be engageable by the gripper arm, and wherein the inner valve is sized to allow access, when attached to the apparatus, by the gripper arm to wafers in the loadlock by rotation of the robot about the axis without a substantial change in the distance of the gripper arm from the axis.

16. A loadlock assembly for attachment in a predetermined orientation to an apparatus operative to process wafers comprising a vacuum chamber in which the wafers are processed at a wafer processing position, and a mechanism for transporting the wafers from the loadlock assembly to the wafer processing position comprising a gripper arm for holding wafers and a robot operable to provide rotational motion of said gripper arm at a fixed radial distance about a predetermined and axis; the loadlock assembly comprising:
first and second loadlocks through which wafers are loaded into the vacuum chamber, the first and second loadlocks having respective first and second outer valves which are selectively operable to seal the loadlocks from the external atmosphere, respective first and second inner valves which are selectively operable to seal the loadlocks from the interior of the vacuum chamber, and respective parts for evacuation and pressurization of the loadlocks, the loadlocks being relatively stacked and arranged when attached to the apparatus to transport wafers in respective planes perpendicular to the axis at the same radial distance from the axis so as to be engageable by the gripper arm, and wherein the first and second inner valves are sized to allow access, when attached to the apparatus, by the gripper arm to wafers in the loadlocks by rotation of the robot about the axis without a substantial change in the distance of the gripper arm from the axis.

17. An apparatus for processing wafers comprising a vacuum chamber in which the wafers are serially processed at a wafer processing position, a loadlock through which the wafers are loaded into the vacuum chamber, and a mechanism for transporting the wafers from the loadlock to the wafer processing position, the loadlock having an outer valve which is selectively operable to seal the loadlock from the external atmosphere, an inner valve which is selectively operable to seal the loadlock from the interior of the vacuum chamber, and a part for evacuation and pressurization of the loadlock, the mechanism for transporting comprising a gripper arm for holding wafers, and a robot operable to provide rotational motion of the gripper arm at a fixed radial distance about a predetermined axis, the loadlock being arranged to transport wafers in a plane perpendicular to the axis at the same radial distance from the axis so as to be engageable by the gripper arm, and wherein the inner valve is sized to allow access by the gripper arm to wafers in the loadlock by rotation of the robot about the axis without a substantial change in the distance of the gripper arm from the axis.

18. An apparatus for processing wafers comprising a vacuum chamber which the wafers are serially processed at a wafer processing position, first and second loadlocks through which the wafers are loaded into the vacuum chamber, and a mechanism for transporting the wafers from the loadlocks to the wafer processing position, the first and second loadlocks having respective first and second outer valves which are selectively operable to seal the loadlocks from the external atmosphere, respective first and second inner valves which are selectively operable to seal the loadlocks from the interior of the vacuum chamber, and respective ports for evacuation and pressurization of the loadlocks, the mechanism for transporting comprising a gripper arm for holding wafers, and a robot operable to provide rotational motion of the gripper arm at a fixed radial distance about a predetermined axis, the loadlocks being relatively stacked and arranged to transport wafers in respective parallel planes perpendicular to the axis at the same radial distance from the axis so as to be engageable by the gripper arm, and wherein the first and second inner valves are sized to allow access by the gripper arm to wafers in the loadlocks by rotation of the robot about the axis without a substantial change in the distance of the gripper arm from the axis.

19. An apparatus according to claim 18, wherein the gripper arm is driven by a robot which requires only axial motion in the direction of the axis about which the gripper arm is pivoted, and rotational motion is about this axis.

20. An apparatus according to claim 18, wherein a second gripper arm is provided which is axially moveable together with the first gripper arm and is rotatable about the axis independently of the first gripper arm.
